(19) United States
(12) Patent Application Publication
(10) Pub. No.: US 2025/0204180 A1
(43) Pub. Date: Jun. 19, 2025

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Xinxin WANG, Beijing (CN); Yang ZHOU, Beijing (CN); Yi QU, Beijing (CN); Song LIU, Beijing (CN); Zhiwen CHU, Beijing (CN); Lei HE, Beijing (CN); Lu BAI, Beijing (CN)

(21) Appl. No.: 18/833,936

(22) PCT Filed: Oct. 10, 2023
(86) PCT No.: PCT/CN2023/123771

§ 371 Date: Jul. 29, 2024

(30) Foreign Application Priority Data
Nov. 29, 2022 (CN) 202211511955.4

(51) Int. Cl. H10K 59/131; H10K 59/80

(52) U.S. Cl. CPC H10K 59/131; H10K 59/873

(57) ABSTRACT

Provided are a display panel and a display apparatus. The display panel comprises a display region (10) and a bezel region located at the periphery of the display region (10), the display region (10) comprises a plurality of data lines (11) and a plurality of sub-pixels (PX), and the plurality of data lines (11) are electrically connected to the plurality of sub-pixels (PX); and the bezel region comprises crack detecting lines (31) and a plurality of detection control units (35), the crack detecting lines (31) are electrically connected to at least one data line (11) among the plurality of data lines (11) by means of the plurality of detection control units (35), each crack detecting line (31) comprises at least one mark pattern (60), and the at least one mark pattern (60) is configured to be an alignment mark in the process.

### CROSS-REFERENCE TO RELATED APPLICATION

The present application is a U.S. National Phase Entry of International Application No. PCT/CN2023/123771 having an international filing date of Oct. 10, 2023, which claims priority of Chinese patent application No. 202211511955.4, filed to CNIPA on Nov. 29, 2022 and entitled “Display Panel and Display Apparatus”. Contents of the above-identified applications are incorporated herein by reference.

### TECHNICAL FIELD

The present disclosure relates to, but is not limited to, the field of display technologies, and more particularly, to a display panel and a display apparatus.

### BACKGROUND

With constant development of display technologies, there are more and more kinds of display products, e.g., a Liquid Crystal Display (LCD), an Organic Light Emitting Diode (OLED) display, a Plasma Display Panel (PDP), a Field Emission Display (FED) and the like.

### SUMMARY

The following is a summary of subject matters described herein in detail. This summary is not intended to limit the protection scope of claims.

In a first aspect, an embodiment of the present disclosure provides a display panel, including a display region and a bezel region located at a periphery of the display region. The display region includes a plurality of data lines and a plurality of sub-pixels, and the plurality of data lines are electrically connected with the plurality of sub-pixels. The bezel region includes a crack detecting line and a plurality of detection control units, the crack detecting line is electrically connected to at least one of the plurality of data lines through the plurality of detection control units, and the crack detecting line includes at least one mark pattern configured as an alignment mark used in a process.

In some examples, the crack detecting line includes a plurality of winding segments, the plurality of winding segments includes a second winding segment and a first winding segment arranged at intervals along a direction away from the display region, and the first winding segment includes the at least one mark pattern.

In some examples, the bezel region includes a first bezel region surrounding the display region and a second bezel region located on a side of the first bezel region away from the display region. The first bezel region includes a first sub-bezel region located between the display region and the second bezel region and a second sub-bezel region located on other sides of the display region. The crack detecting line is located in the first sub-bezel region and the second sub-bezel region, and the mark pattern includes a first sub-mark pattern and a second sub-mark pattern. The first sub-mark pattern is located in the second sub-bezel region, and the second sub-mark pattern is located in the first sub-bezel region.

In some examples, the first winding segment of the crack detecting line in the second sub-bezel region includes a first sub-winding segment extending along a second direction, and the first sub-winding segment is curved to be provided with the first sub-mark pattern. The first sub-mark pattern extends along a first direction away from the display region, and the first direction intersects with the second direction.

In some examples, the first sub-mark pattern is provided as a trapezoidal protrusion including two waist edges and a bottom edge extending along the second direction, and the two waist edges are connected to both ends of the bottom edge, respectively.

In some examples, the length of the bottom edge is 200 microns to 300 microns, and spacing between the bottom edge and the second winding segment is 10 microns to 30 microns.

In some examples, a plurality of first sub-mark patterns are arranged at intervals along the second direction to form a group of first sub-mark patterns, and the first sub-mark patterns in the group of first sub-mark patterns are sequentially connected.

In some examples, a distance between a bottom edge of a first sub-mark pattern located on a side in the second direction in the group of first sub-mark patterns and a bottom edge of a first sub-mark pattern located on the other side in the second direction in the group of first sub-mark patterns is 200 microns to 300 microns.

In some examples, an included angle formed between the waist edge and a direction perpendicular to the bottom edge is 30 degrees to 60 degrees.

In some examples, the crack detecting line in the first sub-bezel region includes a third sub-winding segment extending along a first direction, the third sub-winding segment includes a second sub-mark pattern disposed along a second direction away from the display region, and the first direction intersects with the second direction.

In some examples, the second sub-mark pattern is provided as a boss-shaped protrusion having a length of 70 microns to 90 microns in the first direction and a length of 60 microns to 80 microns in the second direction. Alternatively, the second sub-mark pattern is provided as a step-shaped protrusion having a length of 60 microns to 80 microns in the first direction and a length of 60 microns to 80 microns in the second direction. Alternatively, the second sub-mark pattern is provided as a triangular protrusion having a length of 60 microns to 90 microns in the first direction and a length of 60 microns to 80 microns in the second direction. Alternatively, the second sub-mark pattern is provided as a rhombus-shaped protrusion having a length of 60 microns to 80 microns in the first direction and having a length of 60 microns to 80 microns in the second direction. Alternatively, the rhombus-shaped protrusion has a length of 30 microns to 60 microns in the first direction and the rhombus-shaped protrusion has a length of 60 microns to 80 microns in the second direction. Alternatively, the second sub-mark pattern is provided as a hexagonal protrusion having a length of 120 microns to 130 microns in the first direction and a length of 40 microns to 60 microns in the second direction. Alternatively, the second sub-mark pattern includes a first part and a second part connected to each other, the first part is located on a side of the second part close to the display region, the first part and the second part are both provided as triangles, and a corner of the first part is connected to a corner of the second part.

In some examples, the bezel region includes a plurality of crack detecting lines, the plurality of crack detecting lines are arranged symmetrically with a centerline of the display region as an axis, and mark patterns are arranged symmetrically with the centerline of the display region as the axis.

In some examples, the mark patterns and the crack detecting lines are located in different film layers, and the mark pattern is connected to the crack detecting line through a via.

In some examples, the bezel region further includes a gate drive circuit, a power supply signal line and an isolation dam arranged sequentially at intervals along a direction away from the display region, and the crack detecting line is located between the power supply signal line and the isolation dam.

In a second aspect, an embodiment of the present disclosure provides a display apparatus, including the display panel described in any one of above examples.

Other aspects of the present disclosure may be comprehended after the drawings and the detailed description are read and understood.

### BRIEF DESCRIPTION OF DRAWINGS

Accompanying drawings are used for providing an understanding of technical solutions of the present application and form a part of the specification, are used for explaining the technical solutions of the present application together with embodiments of the present application, and do not constitute a limitation on the technical solutions of the present application.

FIG. 1 is a schematic diagram of a display panel according to an embodiment of the present disclosure.

FIG. 2 is a cross-sectional view of a display panel according to an embodiment of the present disclosure.

FIG. 3 is a first schematic diagram of wirings of a display panel according to an embodiment of the present disclosure.

FIG. 4a is a first schematic diagram of a first sub-mark pattern in a display panel according to an embodiment of the present disclosure.

FIG. 4b is a second schematic diagram of a first sub-mark pattern in a display panel according to an embodiment of the present disclosure.

FIG. 4c is a third schematic diagram of a first sub-mark pattern in a display panel according to an embodiment of the present disclosure.

FIG. 5a is a first schematic diagram of a second sub-mark pattern in a display panel according to an embodiment of the present disclosure.

FIG. 5b is a second schematic diagram of a second sub-mark pattern in a display panel according to an embodiment of the present disclosure.

FIG. 5c is a third schematic diagram of a second sub-mark pattern in a display panel according to an embodiment of the present disclosure.

FIG. 5d is a fourth schematic diagram of a second sub-mark pattern in a display panel according to an embodiment of the present disclosure.

FIG. 5e is a fifth schematic diagram of a second sub-mark pattern in a display panel according to an embodiment of the present disclosure.

FIG. 5f is a sixth schematic diagram of a second sub-mark pattern in a display panel according to an embodiment of the present disclosure.

FIG. 6 is a second schematic diagram of wirings of a display panel according to an embodiment of the present disclosure.

FIG. 7 is a schematic diagram of wirings of a display panel in a related art.

### DETAILED DESCRIPTION

Embodiments of the present disclosure will be described below with reference to the drawings in detail. Implementations may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the drawings schematically illustrate ideal examples, and an implementation of the present disclosure is not limited to shapes, numerical values, or the like shown in the drawings.

Ordinal numerals “first”, “second”, “third”, or the like in the specification are set not to form limits in numbers but only to avoid confusion between constituent elements. In the present disclosure, “a plurality of” represents two or more than two.

In the specification, for convenience, expressions “central”, “above”, “below”, “front”, “back”, “vertical”, “horizontal”, “top”, “bottom”, “inside”, “outside”, or the like for indicating directional or positional relationships are used to illustrate positional relationships between the constituent elements with reference to the drawings, not to indicate or imply that involved devices or elements are required to have specific orientations, or are structured and operated in the specific orientations but only to easily describe the present specification and simplify the description, and thus should not be understood as limitations on the present disclosure. The positional relationships between the constituent elements are changed as appropriate according to a direction in which the constituent elements are described. Therefore, appropriate replacements based on situations are allowed, and the positional relationships are not limited to the expressions in the specification.

In the specification, unless otherwise clearly specified and defined, terms “mounting”, “coupling”, and “connection” should be understood in a broad sense. For example, it may be a fixed connection, a detachable connection, or an integral connection; it may be a mechanical connection or a connection; it may be a direct connection, an indirect connection through a middleware, or an internal communication between two elements. Those of ordinary skills in the art may understand meanings of the aforementioned terms in the present disclosure according to situations.

In the specification, “electrical connection” includes connection of constituent elements through an element with a certain electrical action. The “element with a certain electrical action” is not particularly limited as long as electrical signals may be transmitted between the connected constituent elements. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, to distinguish two electrodes of a transistor except a gate, one of the electrodes is referred to as a first electrode and the other electrode is referred to as a second electrode. The first electrode may be a source or a drain, and the second electrode may be a drain or a source. In addition, a gate of a transistor is referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, and deformation, etc.

In the specification, “about” and “substantially” refer to that a boundary is not defined strictly and a case within a process and measurement error range is allowed. In the specification, “substantially the same” refers to a case where numerical values differ by less than 10%.

In some implementations, in a manufacturing process of display panels, each process stage has its own process detection function, so as to prevent defective products undetected in this process stage from releasing to a next process stage which results in a waste of materials and material costs. Therefore, the manufacturing process of display panels needs to perform effective and rapid detection at each process stage as much as possible, thereby effectively controlling production costs and improving the yield of the display panels.

FIG. 7 is a schematic diagram of wirings of a display panel in a related art. As shown in FIG. 7, the display panel in the related art may include a display region 10 and a bezel region located at a periphery of the display region 10. The bezel region may include a first bezel region 21 surrounding the display region 10, and a second bezel region 22 located on a side of the display region 10. The first bezel region 21 may include a crack detecting line 31 and a mark pattern 60′, and the mark pattern 60′ is located on a side of the crack detecting line 31 away from the display region 10 and arranged at intervals from the crack detecting line 31 in a direction away from the display region 10. Since both the crack detecting line 31 and the mark pattern 60′ occupy a portion of the space of the bezel region, the requirement for a narrow bezel cannot be met.

An embodiment of the present disclosure provides a display panel, including a display region and a bezel region located at a periphery of the display region. The display region includes a plurality of data lines and a plurality of sub-pixels, and the plurality of data lines are electrically connected with the plurality of sub-pixels. The bezel region includes a crack detecting line and a plurality of detection control units, and the crack detecting line is electrically connected to at least one of the plurality of data lines through the plurality of detection control units. The crack detecting line includes at least one mark pattern configured as an alignment mark used in a process.

The crack detecting line of the display panel provided by the present embodiment can receive a detection signal, and the crack detection of the crack detecting line is carried out by using the detection signal to realize the detection to the crack in the bezel region, so as to determine whether the display panel is qualified. In this way, the fast and effective crack detection can be realized, the quality of the display panel can be improved, and the production cost can be reduced.

The display panel of the embodiment of the present disclosure realizes the recognition effect by providing the mark pattern on the crack detecting line and by means of the mark pattern, thereby saving the space of the bezel region. For example, the space of 50 um to 100 um can be saved, and the effect of narrow bezel can be realized.

Solutions of the present embodiment will be described below through some examples.

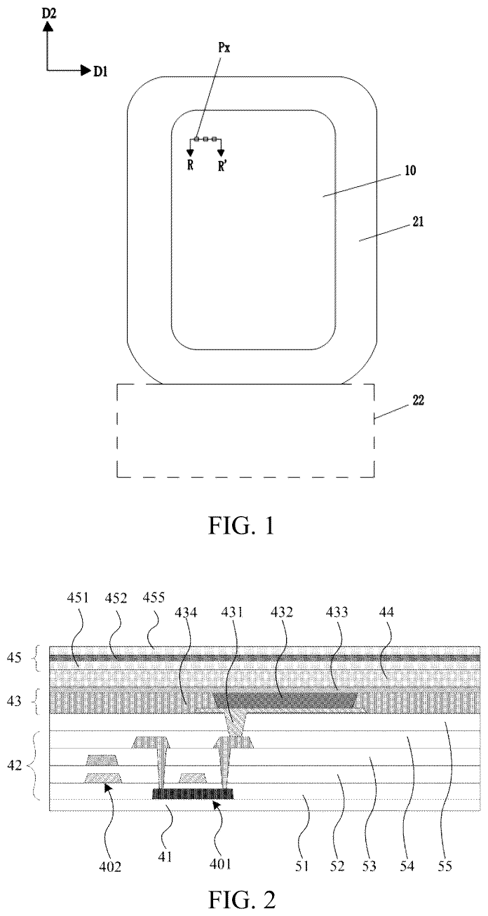

FIG. 1 is a schematic diagram of a display panel according to an embodiment of the present disclosure. In some examples, as shown in FIG. 1, the display panel may include a display region 10 and a bezel region located at a periphery of the display region 10. The bezel region may include a first bezel region 21 surrounding the display region 10, and a second bezel region 22 located on a side of the first bezel region 21 away from the display region 10. The second bezel region 22 may be located on a side of the first bezel region 21 away from the display region 10. In a second direction D2, a part of the first bezel region 21 may be located between the display region 10 and the second bezel region 22.

In some examples, the display region 10 may be a planar region including a plurality of sub-pixels Px that form a pixel array, the plurality of sub-pixels Px may be configured to display a dynamic picture or a static image, and the display region 10 may be referred to as an Active Area (AA). In some examples, a display substrate may be a flexible substrate. Accordingly, the display substrate may be deformable, for example, may be crimped, bent, folded, or curled.

In some examples, as shown in FIG. 1, the display region 10 may be rectangular. However, the present embodiment is not limited thereto. For example, the display region 10 may be in another shape, such as a circle, or an oval.

In some exemplary embodiments, the second bezel region 22 may include a bending region, a drive chip region, and a bonding pin region that are disposed sequentially along a direction away from the display region 10. A fan-out region is connected to the first bezel region 21 and at least includes data fan-out lines. A plurality of data fan-out lines are configured to be connected with the data signal lines of the display region 10 in a fan-out routing manner. The bending region is connected to the fan-out region and may include a composite insulating layer provided with a groove, and is configured to enable the drive chip region and the bonding pin region to be bent to a back of the display region 10. The drive chip region may be provided with a corresponding Integrated Circuit (IC), which may be, for example, a Display Driver Integration (DDI) or a Touch and Display Driver Integration (TDDI). The integrated circuit may be configured to be connected to the plurality of data fan-out lines. The bonding pin region may include a plurality of bonding pins, and the plurality of bonding pins may be configured to bond to an external Flexible Printed Circuit (FPC) such that a plurality of signal leads (e.g., drive control lines, power supply signal lines, etc.) are connected to an external control device through the plurality of bonding pins.

In some examples, the display region 10 may include a substrate, a display structure layer and an encapsulation structure layer disposed on the substrate. The display structure layer may include a plurality of display units (i.e., sub-pixels), a plurality of gate lines, and a plurality of data lines. The plurality of data lines may extend along a first direction D1, and the plurality of gate lines may extend in a second direction D2. Orthogonal projections of the plurality of gate lines on the substrate may intersect with orthogonal projections of the plurality of data lines on the substrate, thereby forming a plurality of sub-pixel regions. One sub-pixel is disposed within one sub-pixel region. The plurality of data lines are electrically connected with the plurality of sub-pixels, and are configured to provide data signals to the plurality of sub-pixels. The plurality of gate lines are electrically connected with the plurality of sub-pixels, and are configured to provide gate drive signals to the plurality of sub-pixels. The first direction D1 intersects with the second direction D2, for example, the first direction D1 may be perpendicular to the second direction D2.

In some examples, three sub-pixels of the display region may form one pixel unit, and the three sub-pixels are a red sub-pixel, a green sub-pixel, and a blue sub-pixel respectively. The three sub-pixels can be arranged in parallel in a horizontal direction, in parallel in a vertical direction or in a “id” manner. However, the present embodiment is not limited thereto. In some other examples, four sub-pixels may form one pixel unit, and the four sub-pixels are a red sub-pixel, a green sub-pixel, a blue sub-pixel, and a white sub-pixel, respectively. The four sub-pixels can be arranged in parallel in a horizontal direction, in parallel in a vertical direction or in a square manner.

In some examples, at least one sub-pixel may include a pixel circuit and a light emitting element. The pixel circuit may be configured to drive a light emitting element connected thereto. For example, the pixel circuit may include a plurality of transistors and at least one capacitor. For example, the pixel circuit may be a circuit of a 3T1C, 4T1C, 5T1C, 5T2C, 6T1C, 7T1C, or 8T1C structure. In the above circuit structure, T refers to a thin film transistor, C refers to a capacitor, a number before T represents a quantity of thin film transistors in the circuit, and a number before C represents a quantity of capacitors in the circuit. In some examples, the plurality of transistors in the pixel circuit may be P-type transistors or may be N-type transistors. Adopting a same type of transistors in the pixel circuit may simplify a process flow, reduce process difficulties of the display panel, and improve a yield of products. In some other examples, the plurality of transistors in the pixel circuit may include a P-type transistor and an N-type transistor.

In some examples, low temperature polysilicon thin film transistors, or oxide thin film transistors, or both of a low temperature polysilicon thin film transistor and an oxide thin film transistor may be used as the plurality of transistors in the pixel circuit. Low Temperature Poly-Silicon (LTPS) is used for an active layer of a low temperature polysilicon thin film transistor and an oxide semiconductor (Oxide) is used for an active layer of an oxide thin film transistor. The low temperature polysilicon thin film transistor has advantages such as a high migration rate and fast charging, and the oxide thin film transistor has advantages such as a low leakage current. The low temperature polysilicon thin film transistor and the oxide thin film transistor are integrated on one display panel, that is, an LTPS+Oxide (LTPO) display panel, so that advantages of both the low temperature polysilicon thin film transistor and the oxide thin film transistor may be utilized, low-frequency drive may be achieved, power consumption may be reduced, and display quality may be improved.

In some examples, the light emitting element may be any one of a light emitting diode (LED), an organic light emitting diode (OLED), a quantum dot light emitting diode (QLED), a micro LED (including a mini-LED or a micro-LED) and the like. For example, the light emitting element may be an OLED, and the light emitting element may emit red light, green light, blue light, or white light or the like under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected to a corresponding pixel circuit. However, the present embodiment is not limited thereto.

In some examples, the display panel may further be integrated with a touch structure. The display region of the display panel may further include a touch structure layer located on a side of the encapsulation structure layer away from the substrate. The touch structure layer may be disposed on the encapsulation structure layer of the display panel to form a Touch on Thin Film Encapsulation (Touch on TFE) structure. The touch structure integrating with a display structure has advantages of lightness and thinness, and foldability or the like, and may meet product requirements such as flexible folding and narrow bezels. The Touch on TFE structure mainly includes a Flexible Multi-Layer On Cell (FMLOC) structure and a Flexible Single-Layer On Cell (FSLOC) structure. The FMLOC structure is based on a working principle of mutual capacitance detection. Generally, a drive (Tx) electrode and a sensing (Rx) electrode are formed by two layers of metal, and an Integrated Circuit (IC) achieves a touch action by detecting a mutual capacitance between the drive electrode and the sensing electrode. The FSLOC structure is based on a working principle of self-capacitance (or voltage) detection. Generally, a touch electrode is formed by a single layer of metal, and an integrated circuit achieves a touch action by detecting the self-capacitance (or voltage) of the touch electrode.

In some examples, the touch structure layer may include a plurality of touch units. At least one touch unit may include at least one touch electrode. An orthographic projection of the at least one touch electrode on the substrate may include orthographic projections of a plurality of sub-pixels on the substrate. When the touch unit includes a plurality of touch electrodes, the plurality of touch electrodes may be disposed at intervals, and adjacent touch electrodes may be connected with each other through a connecting portion. A touch electrode and the connecting portion may be of a same layer structure. In some examples, the touch electrode may be in a shape of rhombus, such as a regular rhombus, a horizontally long rhombus, or a longitudinally long rhombus. However, the present embodiment is not limited thereto. In some examples, the touch electrodes may be in any one or more shapes of a triangle, a square, a trapezoid, a parallelogram, a pentagon, a hexagon, and another polygon.

In some examples, a touch electrode in the display panel may be in a form of a metal mesh. The metal mesh is formed by interweaving a plurality of metal wires, and includes a plurality of mesh patterns. A mesh pattern is a polygon enclosed by a plurality of metal wires. The touch electrode in the form of the metal mesh has advantages of low resistance, small thickness, a quick response speed, etc. However, the present embodiment is not limited thereto.

FIG. 2 is a cross-sectional view of a display panel according to an embodiment of the present disclosure. FIG. 2 may be a schematic partial cross-sectional diagram along a direction R-R′ in FIG. 1. In some examples, as shown in FIGS. 1 and 2, in a direction perpendicular to the display panel, the display region 10 may include a substrate 41, and a drive circuit layer 42, a light emitting element 43, an encapsulation structure layer 44, and a touch structure layer 45 which are disposed in sequence on the substrate 41. In FIG. 2, only a structure of one sub-pixel is taken as an example for illustration.

In some examples, the substrate 41 may be a flexible substrate. The flexible substrate may include a first flexible material layer, a first inorganic material layer, a semiconductor layer, a second flexible material layer and a second inorganic material layer which are stacked. Materials of the first flexible material layer and the second flexible material layer may be polyimide (PI), polyethylene terephthalate (PET), or a polymer soft film for which a surface treatment has been performed, etc. Materials of the first inorganic material layer and the second inorganic material layer may be silicon nitride (SiNx), or silicon oxide (SiOx), etc., for improving water-resistance and oxygen-resistance capabilities of a base substrate. A material of the semiconductor layer may be amorphous silicon (a-si). However, the present embodiment is not limited thereto.

In some examples, as shown in FIG. 2, the drive circuit layer 42 may include a plurality of transistors and at least one storage capacitor which form a pixel circuit. In FIG. 2, a first transistor 401 and a first storage capacitor 402 are taken as an example for illustration. The drive circuit layer 42 in the display region 10 may include a semiconductor layer disposed on the substrate 41, a first insulation layer 51 covering the semiconductor layer, a first gate metal layer disposed on the first insulation layer 51, a second insulation layer 52 covering the first gate metal layer, a second gate metal layer disposed on the second insulation layer 52, a third insulation layer 53 covering the second gate metal layer, and a first source-drain metal layer disposed on the third insulation layer 53. The semiconductor layer may at least include a first active layer. The first gate metal layer may at least include a first gate electrode and a first capacitor electrode. The second gate metal layer may at least include a second capacitor electrode. The first source-drain metal layer may at least include a first source electrode and a first drain electrode. The first active layer, the first gate electrode, the first source electrode, and the first drain electrode may form a first transistor 401. The first capacitor electrode and the second capacitor electrode may form a first storage capacitor 402. In some other examples, the drive circuit layer may further include a sixth insulation layer and a second source-drain metal layer which are located on a side of the first source-drain metal layer away from the substrate. However, the present embodiment is not limited thereto.

In some examples, as shown in FIG. 2, the light emitting element 43 may include a first electrode 431, a pixel definition layer 434, an organic light emitting layer 432, and a second electrode 433. The first electrode 431 is disposed on a fifth insulation layer 55, and is connected with the first drain electrode of the first transistor 401 through vias provided on a fourth insulation layer 54 and the fifth insulation layer 55. The pixel definition layer 434 may be disposed on the first electrode 431 and the fifth insulation layer 55, and may be provided with a pixel opening. The pixel opening may expose a portion of a surface of the first electrode 431. The organic light emitting layer 432 is at least partially disposed in the pixel opening, and the organic light emitting layer 432 is connected with the first electrode 431. The second electrode 433 is disposed on the organic light emitting layer 432, and the second electrode 433 is connected with the organic light emitting layer 432.

In some examples, as shown in FIG. 2, the organic light emitting layer 432 of the light emitting element 43 may include an Emitting Layer (EML), and include one or more film layers of a Hole Injection Layer (HIL), a Hole Transport Layer (HTL), a Hole Block Layer (HBL), an Electron Block Layer (EBL), an Electron Injection Layer (EIL), and an Electron Transport Layer (ETL). When driven by voltages of the first electrode 431 and the second electrode 433, light is emitted according to a required gray scale, in virtue of light emitting characteristics of an organic material. In some examples, light emitting layers of light emitting elements in different colors are different. For example, a red light emitting element includes a red light emitting layer, a green light emitting element includes a green light emitting layer, and a blue light emitting element includes a blue light emitting layer. In order to reduce a process difficulty and improve a yield, a hole injection layer and a hole transport layer located on a side of a light emitting layer may be a common layer, and an electron injection layer and an electron transport layer located on another side of the light emitting layer may be a common layer. In some examples, any one or more layers of the hole injection layer, the hole transport layer, the electron injection layer, and the electron transport layer may be made in one process (one evaporation process or one inkjet printing process), and isolation may be achieved by means of a formed film layer surface segment difference or by means of a surface treatment or the like. For example, any one or more of hole injection layers, hole transport layers, electron injection layers, and electron transport layers corresponding to adjacent sub-pixels may be isolated. In some examples, the organic light emitting layer may be manufactured and formed through evaporation using a Fine Metal Mask (FMM) or an open mask, or manufactured and formed using an inkjet process.

In some examples, as shown in FIG. 2, the encapsulation structure layer 44 may include a first encapsulation layer, a second encapsulation layer, and a third encapsulation layer which are stacked. The first encapsulation layer and the third encapsulation layer may be made of an inorganic material. The second encapsulation layer may be made of an organic material. The second encapsulation layer is disposed between the first encapsulation layer and the third encapsulation layer so as to ensure that external moisture cannot enter the light emitting element 43. However, the present embodiment is not limited thereto. For example, an encapsulation layer may be of a five-layer stacked structure of inorganic/organic/inorganic/organic/inorganic.

In some examples, as shown in FIG. 2, the touch structure layer 45 may include a first touch insulation layer 451 disposed on a side of the encapsulation structure layer 44 away from the substrate 41, a touch electrode layer 452 disposed on a side of the first touch insulation layer 451 away from the substrate 41, and a touch protective layer 455 disposed on a side of the touch electrode layer 452 away from the substrate 41. The touch structure layer in this example is illustrated by taking an FSLOC structure as an example. However, the present embodiment is not limited thereto.

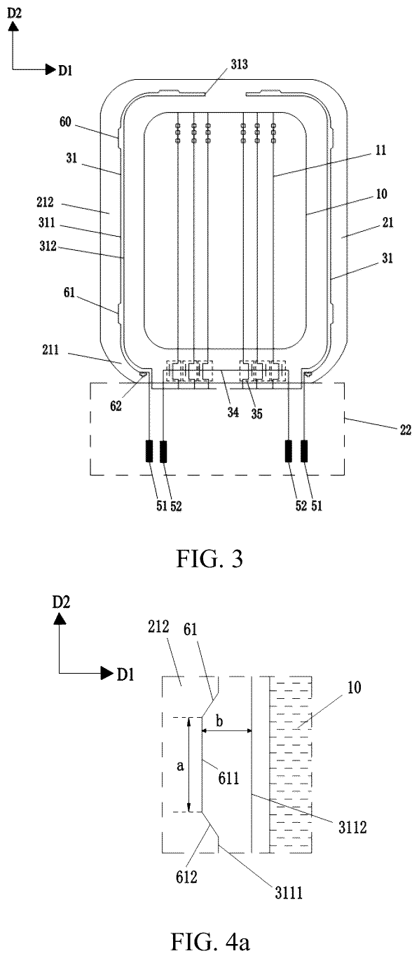

FIG. 3 is a first schematic diagram of wirings of a display panel according to an embodiment of the present disclosure. In FIG. 3, several data lines in the display region and several crack detecting lines in the bezel region are taken as an example for illustration, and other traces are omitted.

In some examples, as shown in FIG. 3, the display region 10 may include a plurality of data lines 11. Each data line 11 may extend along the second direction D2, and the plurality of data lines 11 may be arranged at intervals along the first direction D1. Each data line 11 may be electrically connected with a plurality of display units Px arranged in the second direction D2, and is configured to supply data signals to the plurality of display units Px. For example, the data lines 11 may be configured to be electrically connected with display units that emit light of a same color. For example, the data lines 11 may be configured to be electrically connected with a plurality of display units that emit green light. However, the present embodiment is not limited thereto. The first direction D1 intersects with the second direction D2, for example, the first direction D1 may be perpendicular to the second direction D2.

In some examples, as shown in FIG. 3, the bezel region may include a plurality of detection control units 35 and a detection control line 34. The plurality of detection control units may be located in the first bezel region 21, for example, the plurality of detection control units may be arranged at intervals along the first direction D1, and the plurality of detection control units may be located between the display region 10 and the second bezel region 22. The detection control line 34 may be located in the first bezel region 21 and between the display region 10 and the second bezel region 22, and the detection control line 34 is electrically connected to the detection control units 35. However, the present embodiment is not limited thereto. In other examples, the plurality of detection control units may be located in the second bezel region.

In some examples, as shown in FIG. 3, one crack detecting line 31 may be electrically connected to one detection control unit 35, and one detection control unit 35 may be electrically connected to at least one data line 11. One crack detecting line 31 may be electrically connected to at least one data line 11 through one detection control unit 35.

In some examples, as shown in FIG. 3, the crack detecting line 31 may be serpentine line. The serpentine line is a bending curve. For example, after one end of the line extends along one direction for a certain distance, it bends circuitously and extends along a direction opposite to this direction for a certain distance, and bends circuitously again and extends along this direction. In this way, circuitous bending is repeated for several times to form the serpentine line. In this example, the crack detecting line 31 may be wound in a direction of the first bezel region 21 away from the display region 10.

In some examples, as shown in FIG. 3, the second bezel region 22 may include a first signal pin 51 and a second signal pin 52. A first end of the crack detecting line 31 may be electrically connected to the detection control unit 35, and a second end of the crack detecting line 31 may be connected to the first signal pin 51 on the second bezel region 22. The first signal pin 51 can be used as a test pin. For example, by providing a test signal through the first signal pin 51, crack detection can be carried out on the crack detecting line.

In some examples, as shown in FIG. 3, the detection control unit 35 may include a detection transistor. A gate of the detection transistor may be electrically connected with the detection control line 34, a first electrode of the detection transistor may be electrically connected with the first end of the crack detecting line, and a second electrode of the detection transistor may be electrically connected with the data line 11 in the display region 10. One end of the detection control line 34 may be electrically connected to the second signal pin 52 of the second bezel region 22. In this example, the detection control line 34 may provide a detection control signal through the second signal pin 52, and is configured to turn on or off a plurality of detection control units.

During crack detection, the detection control signal supplied by the detection control line 34 may cause the detection transistor to be turned on, thereby causing the detection control unit 35 to be turned on. The crack detecting line 31 can receive a test signal through the first signal pin 51, and the test signal is transmitted to the display unit of the display region 10 through the data line 11 of the display region 10. The test signal drives the display unit to display, so as to determine whether the crack detecting line 31 connected thereto is cracked by whether the display unit is displaying.

In some examples, as shown in FIG. 3, the crack detecting line 31 may include a plurality of winding segments arranged at intervals in a direction away from the display region 10, and a winding segment 311 located on a side away from the display region 10 of the plurality of winding segments includes a mark pattern 60 extending along a direction away from the display region 10. At least one mark pattern 60 is configured as an alignment mark used in the process, and the mark pattern 60 can be used for accuracy detection and identification alignment of various process sections (e.g., process sections such as cutting, attachment, bending of second bezel region).

In some examples, as shown in FIG. 3, the crack detecting line 31 may include a second winding segment 312 and a first winding segment 311 arranged at intervals along a direction away from the display region 100, and a connection segment 313 connecting an end of the second winding segment 312 and an end of the first winding segment 311. The connection segment 313 may be arcuate in shape. The first winding segment 311 is located on a side of the second winding segment 312 away from the display region 100, and the first winding segment 311 includes at least one mark pattern 60.

The mark pattern 60 is clearly distinguished in shape from the other traces in the bezel region to facilitate identification. For example, the mark pattern 60 may be provided in a shape of a triangle, a rectangle, a trapezoid, a rhombus, a polygon, or a shape formed from the combination of polygons.

The display panel of the embodiment of the present disclosure realizes the recognition effect by providing the mark pattern on the crack detecting line and by means of the mark pattern, thereby saving the space of the bezel region. For example, the space of 50 um to 100 um can be saved, and the effect of narrow bezel can be realized.

In some examples, as shown in FIG. 3, the first bezel region 21 may include a first sub-bezel region 211 located between the display region 10 and the second bezel region 22 and a second sub-bezel region 212 located on other sides of the display region 10. For example, the display region 10 is rectangular, the first bezel region 21 may be a rectangular ring, and the first bezel region 21 includes one first sub-bezel region 211 located between the display region 10 and the second bezel region 22, and three second sub-bezel regions 212 located on other sides of the display region 10. The first sub-bezel region 211 and the three second sub-bezel regions 212 form a rectangular ring-shaped first bezel region 21.

In some examples, as shown in FIG. 3, the crack detecting line 31 may be located in the first sub-bezel region 211 and the second sub-bezel region 212. The mark pattern 60 includes a first sub-mark pattern 61 and a second sub-mark pattern 62, the first sub-mark pattern 61 is located in the second sub-bezel region 212 and the second sub-mark pattern 62 is located in the first sub-bezel region 211. The first sub-mark pattern 61 is used for accuracy detection after cutting the display panel, and the second sub-mark pattern 62 is used for accuracy detection after cutting the display panel and alignment of the bonding process of the second bezel region 22.

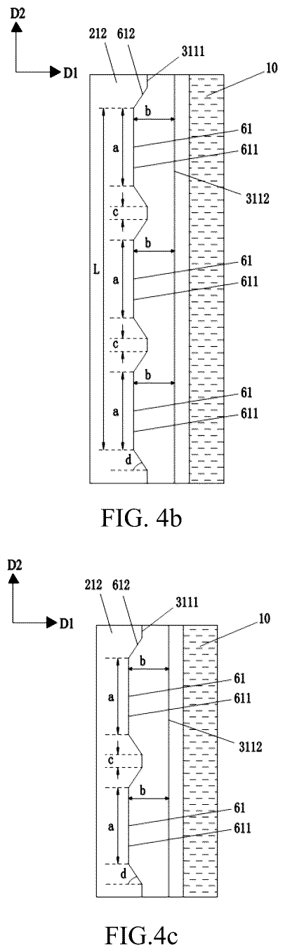

FIG. 4a is a first schematic diagram of a first sub-mark pattern in a display panel according to an embodiment of the present disclosure. In some examples, as shown in FIG. 4a, the first winding segment 311 of the crack detecting line 31 in the second sub-bezel region 212 may include a first sub-winding segment 3111 extending along the second direction D2, and the second winding segment 312 of the crack detecting line 31 in the second sub-bezel region 212 may include a second sub-winding segment 3112 extending along the second direction D2. The first sub-winding segment 3111 and the second sub-winding segment 3112 are arranged at intervals along the first direction D1, and the first sub-winding segment 3111 is located on a side of the second sub-winding segment 3112 away from the display region 10. The first sub-winding segment 3111 includes at least one first sub-mark pattern 61 extending along the first direction D1 away from the display region 10, and the first sub-mark pattern 61 is provided as a trapezoidal protrusion. The trapezoidal protrusion includes two waist edges 612 and one bottom edge 611 extending along the second direction D2, the two waist edges 612 respectively connect both ends of the bottom edge 611 with the first sub-winding segment 3111, and the two waist edges 612 respectively form obtuse angles with the bottom edge 611.

In some embodiments, the first sub-mark pattern may also employ a protrusion of other shapes, such as a triangle, a rhombus, a rectangle, a hexagon, and a step.

In some examples, as shown in FIG. 4a, a length a of the bottom edge 611 in the second direction D2 is 200 microns to 300 microns, for example, the length a of the bottom edge 611 in the second direction D2 is 220 microns to 260 microns. A spacing b between the bottom edge 611 and the second sub-winding segment 3112 is 10 microns to 30 microns, for example, the spacing b between the bottom edge 611 and the second sub-winding segment 3112 is 15 microns to 20 microns.

FIG. 4b is a second schematic diagram of a first sub-mark pattern in a display panel according to an embodiment of the present disclosure. FIG. 4c is a third schematic diagram of a first sub-mark pattern in a display panel according to an embodiment of the present disclosure. In some examples, a plurality of first sub-mark patterns 61 are arranged at intervals along the second direction D2 to form a group of first sub-mark patterns, and each of the first sub-mark patterns 61 in the group of first sub-mark patterns is connected in sequence. For example, three first sub-mark patterns 61 are arranged at intervals along the second direction D2 to form one group of first sub-mark patterns, the three first sub-mark patterns 61 are sequentially connected, and the three first sub-mark patterns 61 are all trapezoidal protrusions, as shown in FIG. 4b. Alternatively, two first sub-mark patterns 61 are arranged at intervals along the second direction D2 to form one group of first sub-mark patterns, the two first sub-mark patterns 61 are sequentially connected, and the two first sub-mark patterns 61 are both trapezoidal protrusions, as shown in FIG. 4c.

In some examples, a distance L between the bottom edge of the first sub-mark pattern 61 located on a side in the second direction D2 in the group of first sub-mark patterns and the bottom edge of the first sub-mark pattern 61 located on the other side in the second direction D2 in the group of first sub-mark patterns is 200 microns to 300 microns.

For example, as shown in FIG. 4b, the three first sub-mark patterns 61 are arranged at intervals along the second direction D2 to form one group of first sub-mark patterns. The length a of the bottom edge 611 in each first sub-mark pattern 61 in the second direction D2 is 80 microns, and the spacing c between the adjacent first sub-mark patterns 61 is 10 microns. The distance L between the bottom edge of the first sub-mark pattern 61 located on a side in the second direction D2 in the group of first sub-mark patterns and the bottom edge of the first sub-mark pattern 61 located on the other side in the second direction D2 in the group of first sub-mark patterns is 260 microns.

For example, as shown in FIG. 4c, the two first sub-mark patterns 61 are arranged at intervals along the second direction D2 to form one group of first sub-mark patterns. The length a of the bottom edge 611 in each first sub-mark pattern 61 in the second direction D2 is 120 microns, the spacing c between adjacent first sub-mark patterns 61 is 10 microns, and the distance L between the bottom edge of one first sub-mark pattern 61 and the bottom edge of another first sub-mark pattern 61 is 260 microns.

In some examples, as shown in FIG. 4b and FIG. 4c, an included angle d formed between the waist edge 612 of the first sub-mark pattern 61 and the first direction D1 perpendicular to the bottom edge 611 is 30 degrees to 60 degrees. For example, an included angle d formed between the waist edge 612 of the first sub-mark pattern 61 and the first direction D1 perpendicular to the bottom edge 611 is 45 degrees to 55 degrees.

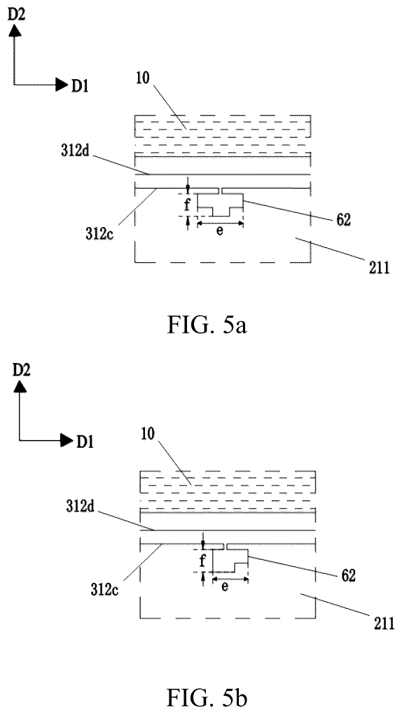

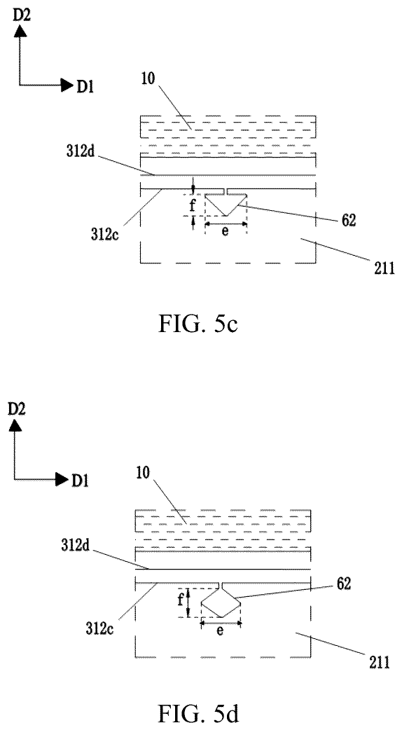

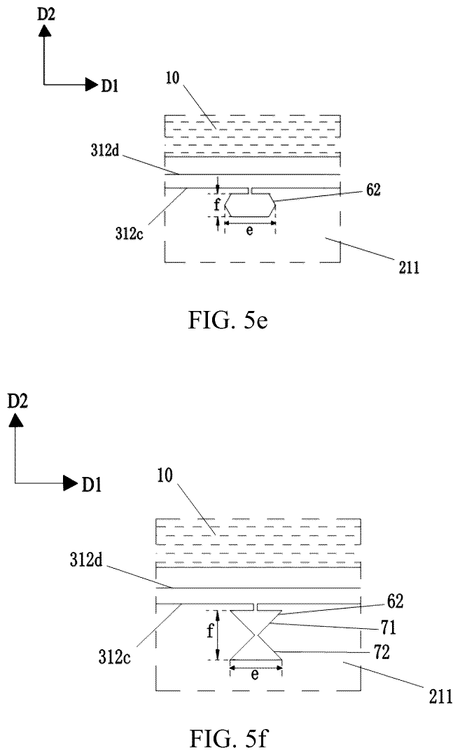

FIG. 5a is a first schematic diagram of a second sub-mark pattern in a display panel according to an embodiment of the present disclosure. In some examples, as shown in FIG. 5a, the crack detecting line 31 of the first sub-bezel region 211 may include one third sub-winding segment 312c extending along the first direction D1 and one fourth sub-winding segment 312d extending along the first direction D1, the third sub-winding segment 312c and the fourth sub-winding segment 312d are arranged at intervals along the second direction D2, and the third sub-winding segment 312c is located on a side of the fourth sub-winding segment 312d away from the display region 10. The third sub-winding segment 312c may be connected to the first sub-winding segment 3111, and the fourth sub-winding segment 312d may be connected to the first winding segment 311. The third sub-winding segment 312c is curved to be provided with a second sub-mark pattern 62 extending along the first direction D1 away from the display region 10, and the second sub-mark pattern 62 is provided as a boss-shaped protrusion. A length e of the boss-shaped protrusion in the first direction D1 is 50 microns to 100 microns, for example, the length e of the boss-shaped protrusion in the first direction D1 is 70 microns to 90 microns. A length f of the boss-shaped protrusion in the second direction D2 is 40 microns to 100 microns, for example, the length f of the boss-shaped protrusion in the second direction D2 is 60 microns to 80 microns. The length e in the first direction D1 is a distance between an edge on one side of the second sub-mark pattern 62 in the first direction D1 and an edge on the other side of the second sub-mark pattern 62 in the first direction D1. The length f in the second direction D2 is a distance between an edge on one side of the second sub-mark pattern 62 in the second direction D2 and an edge on the other side of the second sub-mark pattern 62 in the second direction D2.

FIG. 5b is a second schematic diagram of a second sub-mark pattern in a display panel according to an embodiment of the present disclosure. In some examples, as shown in FIG. 5b, the second sub-mark pattern 62 is provided as a step-shaped protrusion. The length e of the step-shaped protrusion in the first direction D1 is 40 microns to 100 microns, for example, the length e of the step-shaped protrusion in the first direction D1 is 60 microns to 80 microns. The length f of the step-shaped protrusion in the second direction D2 is 40 microns to 100 microns, for example, the length f of the step-shaped protrusion in the second direction D2 is 60 microns to 80 microns.

FIG. 5c is a third schematic diagram of a second sub-mark pattern in a display panel according to an embodiment of the present disclosure. In some examples, as shown in FIG. 5c, the second sub-mark pattern 62 is provided as a triangular protrusion. The corners of the triangular protrusion are rounded. The length e of the triangular protrusion in the first direction D1 is 40 microns to 100 microns, for example, the length e of the triangular protrusion in the first direction D1 is 60 microns to 90 microns. The length f of the triangular protrusion in the second direction D2 is 40 microns to 100 microns, for example, the length f of the triangular protrusion in the second direction D2 is 60 microns to 80 microns.

FIG. 5d is a fourth schematic diagram of a second sub-mark pattern in a display panel according to an embodiment of the present disclosure. In some examples, as shown in FIG. 5d, the second sub-mark pattern 62 is provided as a rhombus-shaped protrusion. The length e of the rhombus-shaped protrusion in the first direction D1 is 60 microns to 80 microns, and the length f of the rhombus-shaped protrusion in the second direction D2 is 60 microns to 80 microns. Alternatively, the length e of the rhombus-shaped protrusion in the first direction D1 is 30 microns to 60 microns, and the length f of the rhombus-shaped protrusion in the second direction D2 is 60 microns to 80 microns.

FIG. 5e is a fifth schematic diagram of a second sub-mark pattern in a display panel according to an embodiment of the present disclosure. In some examples, as shown in FIG. 5e, the second sub-mark pattern 62 is provided as a hexagonal protrusion. The length e of the hexagonal protrusion in the first direction D1 is 100 microns to 150 microns, for example, the length e of the hexagonal protrusion in the first direction D1 is 120 microns to 130 microns. The length f of the hexagonal protrusion in the second direction D2 is 20 microns to 80 microns. For example, the length f of the hexagonal protrusion in the second direction D2 is 40 microns to 60 microns.

FIG. 5f is a sixth schematic diagram of a second sub-mark pattern in a display panel according to an embodiment of the present disclosure. In some examples, as shown in FIG. 5f, the second sub-mark pattern 62 includes a first part 71 and a second part 72 connected to each other, the first part 71 is located on a side of the second part 72 close to the display region 10, the first part 71 and the second part 72 are both triangular, and a corner of the first part 71 is connected to a corner of the second part 72. The length e of the second sub-mark pattern 62 in the first direction D1 is 10 microns to 60 microns, for example, the length e of the second sub-mark pattern 62 in the first direction D1 is 30 microns to 50 microns. The length f of the second sub-mark pattern 62 in the second direction D2 is 20 microns to 80 microns. For example, the length f of the second sub-mark pattern 62 in the second direction D2 is 40 microns to 60 microns.

In some examples, the mark pattern on the crack detecting line may be disposed in the same layer as the crack detecting line (e.g., the winding segment and the connection segment) and integrally formed with the crack detecting line. For example, the winding segment, the connection segment and the mark pattern of the crack detecting line are all disposed in the same layer as a second gate metal layer of the drive circuit layer in the display region.

In some embodiments, the mark pattern on the crack detecting line may be located in a different film layer from the crack detecting line (e.g., the winding segment and the connection segment). The mark pattern can be connected with the winding segment of the crack detecting line through a via, so as to increase the recognition of the mark pattern.

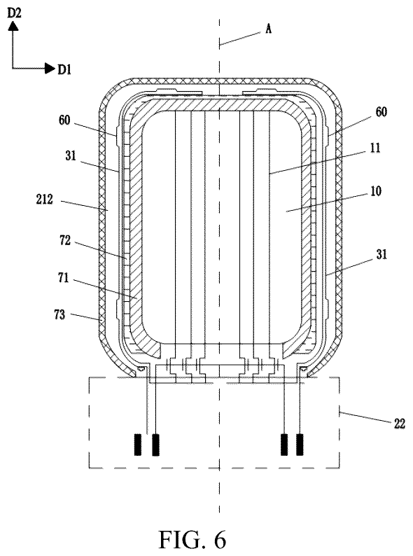

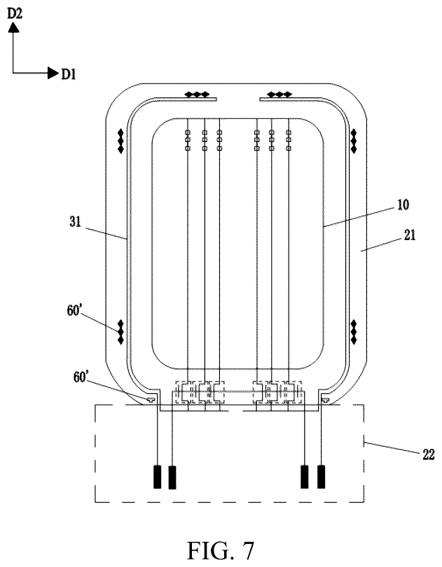

FIG. 6 is a second schematic diagram of wirings of a display panel according to an embodiment of the present disclosure. As shown in FIG. 6, the first sub-bezel region 212 further includes a gate drive circuit (GOA circuit) 71, a power supply signal line 72, and an isolation dam 73. The gate drive circuit (GOA circuit) 71, the power supply signal line 72 and the isolation dam 73 are all disposed around a periphery of the display region 10, and the gate drive circuit (GOA circuit) 71, the power supply signal line 72, and the isolation dam 73 are arranged at intervals and in sequence in a direction away from the display region 10. The crack detecting line 31 is located between the power supply signal line 72 and the isolation dam 73, the mark pattern 60 of the crack detecting line 31 is located between the power supply signal line 72 and the isolation dam 73, and the mark pattern 60 extend in a direction close to the isolation dam 73 and is arranged at intervals from the isolation dam 73.

In some examples, as shown in FIG. 6, the bezel region may include a plurality of crack detecting lines 31. The plurality of crack detecting lines 31 are substantially symmetrical with a centerline A of the display region in the second direction D2 as an axis, and the mark patterns 60 are substantially symmetrical with the centerline A of the display region in the second direction D2 as the axis. For example, the first bezel region 21 may include two crack detecting lines 31, which may be substantially symmetrical with respect to the centerline A of the display panel along the second direction D2. One crack detecting line 31 may be located in a left half region of the first bezel region 21, and one crack detecting line 31 may be located in a right half region of the first bezel region 21. The mark patterns 60 on the two crack detecting lines 31 are substantially symmetrical with the centerline A of the display region in the second direction D2 as the axis, and the mark patterns 60 on one crack detecting line 31 may be located in the left half region of the first bezel region 21, and the mark patterns 60 on one crack detecting line 31 may be located in the right half region of the first bezel region 21.

An embodiment of the present disclosure further provides a display apparatus, including the display panel described in any one of above embodiments. The display apparatus includes a mobile phone, a tablet computer, a wearable smart product (such as a smart watch, a bracelet, or the like), a personal digital assistant (PDA), a vehicle-mounted computer, or the like. A specific form of the above display apparatus is not specially limited in the embodiments of the present application.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display panel, comprising a display region and a bezel region located at a periphery of the display region, wherein the display region comprises a plurality of data lines and a plurality of sub-pixels, and the plurality of data lines are electrically connected with the plurality of sub-pixels; the bezel region comprises a crack detecting line and a plurality of detection control units, the crack detecting line is electrically connected to at least one of the plurality of data lines through the plurality of detection control units, and the crack detecting line comprises at least one mark pattern configured as an alignment mark used in a process.

2. The display panel according to claim 1, wherein the crack detecting line comprises a plurality of winding segments, the plurality of winding segments comprises a second winding segment and a first winding segment arranged at intervals along a direction away from the display region, and the first winding segment comprises the at least one mark pattern.

3. The display panel according to claim 2, wherein the bezel region comprises a first bezel region surrounding the display region and a second bezel region located on a side of the first bezel region away from the display region, the first bezel region comprises a first sub-bezel region located between the display region and the second bezel region and a second sub-bezel region located on other sides of the display region, the crack detecting line is located in the first sub-bezel region and the second sub-bezel region, the mark pattern comprises a first sub-mark pattern and a second sub-mark pattern, the first sub-mark pattern is located in the second sub-bezel region, and the second sub-mark pattern is located in the first sub-bezel region.

4. The display panel according to claim 3, wherein the first winding segment of the crack detecting line in the second sub-bezel region comprises a first sub-winding segment extending along a second direction, the first sub-winding segment is curved to be provided with the first sub-mark pattern, the first sub-mark pattern extends along a first direction away from the display region, and the first direction intersects with the second direction.

5. The display panel according to claim 4, wherein the first sub-mark pattern is provided as a trapezoidal protrusion comprising two waist edges and a bottom edge extending along the second direction, and the two waist edges are connected to both ends of the bottom edge, respectively.

6. The display panel according to claim 5, wherein a length of the bottom edge is 200 microns to 300 microns, and spacing between the bottom edge and the second winding segment is 10 microns to 30 microns.

7. The display panel according to claim 5, wherein a plurality of first sub-mark patterns are arranged at intervals along the second direction to form a group of first sub-mark patterns, and the first sub-mark patterns in the group of first sub-mark patterns are sequentially connected.

8. The display panel according to claim 7, wherein a distance between a bottom edge of a first sub-mark pattern located on a side in the second direction in the group of first sub-mark patterns and a bottom edge of a first sub-mark pattern located on the other side in the second direction in the group of first sub-mark patterns is 200 microns to 300 microns.

9. The display panel according to claim 5, wherein an included angle formed between the waist edge and a direction perpendicular to the bottom edge is 30 degrees to 60 degrees.

10. The display panel according to claim 3, wherein the crack detecting line in the first sub-bezel region comprises a third sub-winding segment extending along a first direction, the third sub-winding segment comprises a second sub-mark pattern disposed along a second direction away from the display region, and the first direction intersects with the second direction.

11. The display panel according to claim 10, wherein the second sub-mark pattern is provided as a boss-shaped protrusion having a length of 70 microns to 90 microns in the first direction and a length of 60 microns to 80 microns in the second direction; or, the second sub-mark pattern is provided as a step-shaped protrusion having a length of 60 microns to 80 microns in the first direction and a length of 60 microns to 80 microns in the second direction; or, the second sub-mark pattern is provided as a triangular protrusion having a length of 60 microns to 90 microns in the first direction and a length of 60 microns to 80 microns in the second direction; or, the second sub-mark pattern is provided as a rhombus-shaped protrusion having a length of 60 microns to 80 microns in the first direction and having a length of 60 microns to 80 microns in the second direction; or, the rhombus-shaped protrusion has a length of 30 microns to 60 microns in the first direction and the rhombus-shaped protrusion has a length of 60 microns to 80 microns in the second direction; or, the second sub-mark pattern is provided as a hexagonal protrusion having a length of 120 microns to 130 microns in the first direction and a length of 40 microns to 60 microns in the second direction; or, the second sub-mark pattern comprises a first part and a second part connected to each other, the first part is located on a side of the second part close to the display region, the first part and the second part are both provided as triangles, and a corner of the first part is connected to a corner of the second part.

12. The display panel according to claim 1, wherein the bezel region comprises a plurality of crack detecting lines, the plurality of crack detecting lines are arranged symmetrically with a centerline of the display region as an axis, and mark patterns are arranged symmetrically with the centerline of the display region as the axis.

13. The display panel according to claim 1, wherein the mark pattern and the crack detecting line are located in different film layers, and the mark pattern is connected to the crack detecting line through a via.

14. The display panel according to claim 1, wherein the bezel region further comprises a gate drive circuit, a power supply signal line and an isolation dam arranged sequentially at intervals along a direction away from the display region, the crack detecting line is located between the power supply signal line and the isolation dam.

15. A display apparatus, comprising the display panel according to claim 1.

16. The display panel according to claim 2, wherein the bezel region comprises a plurality of crack detecting lines, the plurality of crack detecting lines are arranged symmetrically with a centerline of the display region as an axis, and mark patterns are arranged symmetrically with the centerline of the display region as the axis.

17. The display panel according to claim 3, wherein the bezel region comprises a plurality of crack detecting lines, the plurality of crack detecting lines are arranged symmetrically with a centerline of the display region as an axis, and mark patterns are arranged symmetrically with the centerline of the display region as the axis.

18. The display panel according to claim 2, wherein the mark pattern and the crack detecting line are located in different film layers, and the mark pattern is connected to the crack detecting line through a via.

19. The display panel according to claim 3, wherein the mark pattern and the crack detecting line are located in different film layers, and the mark pattern is connected to the crack detecting line through a via.

20. The display panel according to claim 2, wherein the bezel region further comprises a gate drive circuit, a power supply signal line and an isolation dam arranged sequentially at intervals along a direction away from the display region, the crack detecting line is located between the power supply signal line and the isolation dam.
